(19) United States
(12) Patent Application Publication
(10) Pub. No.: US 2026/0055317 A1
(43) Pub. Date: Feb. 26, 2026

(54) METHOD OF MANUFACTURING QUANTUM DOT, QUANTUM DOT, AND ELECTRONIC DEVICE INCLUDING THE SAME

(71) Applicants: Samsung Display Co., Ltd., Yongin-si (KR); Hongik University Industry-Academia Cooperation Foundation, Seoul (KR)

(72) Inventors: YOUNGSOO KWON, Yongin-si (KR); Heesun Yang, Seoul (KR); Yuri Kim, Seoul (KR); KEUNCHAN OH, Yongin-si (KR); KIHEON LEE, Yongin-si (KR); MYUNGJIN LEE, Yongin-si (KR); HYEOKJIN LEE, Yongin-si (KR)

(21) Appl. No.: 19/246,183

(22) Filed: Jun. 23, 2025

(30) Foreign Application Priority Data
Aug. 21, 2024 (KR) 10-2024-0111936

(51) Int. Cl. C09K 11/62; B82Y 20/00; B82Y 40/00; C09K 11/58; H10H 20/01; H10H 20/851

(52) U.S. Cl. CPC C09K 11/621; B82Y 40/00; C09K 11/582; H10H 20/0361; H10H 20/8512; B82Y 20/00

(57) ABSTRACT

A method of manufacturing a quantum dot includes forming a core including silver (Ag) and indium (In), purifying the core with a surface treatment solution including gallium (Ga) and forming a shell around (e.g., surrounding) the core by reacting a first precursor including gallium (Ga) with the core.

### CROSS-REFERENCE TO RELATED APPLICATION

The present application claims priority to and the benefit of Korean Patent Application No. 10-2024-0111936, filed on Aug. 21, 2024, in the Korean Intellectual Property Office, the entire content of which is incorporated herein by reference.

### BACKGROUND

### 1. Field

Embodiments relate to a method of manufacturing a quantum dot, the quantum dot manufactured utilizing the method, a display device including the quantum dot, and an electronic device including the quantum dot. The method may be a method of manufacturing a red light-emitting quantum dot, the quantum dot manufactured utilizing the method, the display device including the same, and the electronic device including the same.

### 2. Description of the Related Art

A quantum dot is a nano-sized semiconductor nanocrystal that exhibits a quantum confinement effect. By controlling size and composition of the nanocrystal, it may have different energy band gaps and thus emit light at one or more suitable emission wavelengths. The quantum dot may include a core, a shell surrounding the core, and a ligand that is formed on the surface of the shell and chemically bonds to it.

A display device is a device that displays an image to provide visual information to a user. Recently, research has been conducted on using quantum dots in the manufacture of display devices.

### SUMMARY

An aspect according to one or more embodiments of the present disclosure is directed toward a method of manufacturing a quantum dot with improved or enhanced process economy.

Aspects according to one or more embodiments of the present disclosure are directed toward a quantum dot manufactured utilizing the method, a display device including the same and an electronic device including the same, each with improved light-emitting characteristics.

Additional aspects of embodiments will be set forth in part in the description, which follows and, in part, will be apparent from the description, or may be learned by practice of the presented embodiments of the disclosure.

A method of manufacturing a quantum dot according to one or more embodiments may include forming a core including silver (Ag) and indium (In), purifying the core with a surface treatment solution including gallium (Ga) (e.g., Ga-containing compound), and forming a shell around (e.g., surrounding) the core by reacting a first precursor including gallium (Ga) (e.g., a Ga-containing precursor) with the core.

In one or more embodiments, the surface treatment solution may include at least one selected from among Gals and Ga(acac)₃.

In one or more embodiments, the purifying of the core may be performed between the forming of the core and the forming of the shell.

In one or more embodiments, after the purifying of the core, a peak emission wavelength of a photoluminescence (PL) spectrum of the core may be about 600 nm or more (e.g., more than 600 nm).

In one or more embodiments, the forming of the core may include adding a second precursor including silver (Ag) (e.g., a Ag-containing precursor) and a third precursor including indium (In) (e.g., an In-containing precursor) to a reaction vessel and adding sulfur(S) to the reaction vessel.

In one or more embodiments, the second precursor may include at least one selected from among AgF, AgCl, AgBr, AgI, Ag(NO₃), Ag(OAc), Ag(acac), and Ag(DDTC).

In one or more embodiments, the third precursor may include at least one selected from among InF₃, InCl₃, InBr₃, InI₃, In(NO₃)₃, In(OAc)₃, In(acac)₃, and In(DDTC)₃.

In one or more embodiments, the adding of the third precursor may be performed at a first temperature, and the adding of sulfur may be performed at a second temperature over a first duration (e.g., during a first time period).

In one or more embodiments, the second temperature may be greater than the first temperature, and the second temperature may be greater than about 220° C.

In one or more embodiments, in the purifying of the core, the core and the surface treatment solution may react at a third temperature which is less than the second temperature.

In one or more embodiments, in the purifying of the core, the core and the surface treatment solution may react over a second duration (e.g., during a second time period) which is greater than the first duration.

In one or more embodiments, the method may further include adding a ligand to the core at a fourth temperature which is less than the third temperature between the purifying of the core and forming of the shell.

In one or more embodiments, in forming of the shell, sulfur may be added to react with the core and the first precursor.

In one or more embodiments, the first precursor may include at least one selected from among GaF₃, GaCl₃, GaBr₃, GaI₃, Ga(NO₃)₃, Ga(OAc)₃, Ga(acac)₃ and Ga(DDTC)₃.

In one or more embodiments, the core may include AgInS₂.

In one or more embodiments, the shell may include the gallium (Ga).

A quantum dot according to one or more embodiments may include a core including silver (Ag) and indium (In) and a shell around (e.g., surrounding) the core, and including gallium (Ga) and sulfur(S), and a full width at a half maximum of an emission wavelength of the quantum dot may be about 50 nm or less, and a peak emission wavelength of a PL spectrum of the quantum dot may be about 600 nm or more.

In one or more embodiments, an average diameter of the core may be about 4.5 nm or more and about 12 nm or less

A display device according to one or more embodiments may include a substrate including a light-emitting area and a non-light-emitting area adjacent to the light-emitting area, a color conversion pattern arranged on the substrate in the light-emitting area, and a light-blocking pattern on the substrate in the non-light-emitting area, and adjacent to the color conversion pattern. The color conversion pattern includes a quantum dot having a full width at half maximum of an emission wavelength of about 50 nm or less, and a peak emission wavelength length of more than 600 nm, the quantum dot including a core which includes silver (Ag) and indium (In) and a shell around (e.g., surrounding) the core and includes gallium (Ga); and a resin portion around the quantum dot.

In one or more embodiments, an average diameter of the core may be about 4.5 nm or more and about 12 nm or less. An electronic device according to one or more embodiments includes the quantum dot.

In the method of manufacturing the quantum dot according to one or more embodiments of the present disclosure, purifying the core with the surface treatment solution, which is performed after the forming of the core, allows the peak emission wavelength of the core to be confirmed (e.g., whether it meets a set or predetermined emission wavelength) before the shell is formed. Accordingly, because the quality of the quantum dot can be assessed (e.g., easily determined) during the process of manufacturing the quantum dot, cost and efficiency of the quantum dot manufacturing process may be improved. In addition, the quantum dot having a substantially uniform size may be more easily manufactured.

In the quantum dot according to one or more embodiments of the present disclosure, an average diameter of the core may be about 4.5 nm or more, and a full width at a half maximum of the emission wavelength may be about 50 nm or less. Accordingly, because the quantum dot has the core of a bulk (e.g., large) size and has a narrow emission half-width, an emission efficiency of the quantum dot may be improved.

In a display device according to one or more embodiments of the present disclosure, the average diameter of the core may be about 4.5 nm or more, and a full width at a half maximum of the emission wavelength may be about 50 nm or less. Accordingly, a display quality of the display device may be improved.

In the display device according to one or more embodiments, an upper surface of the pixel electrode may be formed to be flat by removing a stepped (e.g., uneven) portion of the pixel electrode. For example, the stepped portion of the pixel electrode may be removed by forming the opening of the pixel electrode in the stepped portion. Accordingly, a diffused reflection may be reduced.

### BRIEF DESCRIPTION OF THE DRAWINGS

Illustrative, non-limiting embodiments will be more clearly understood from the following detailed description in conjunction with the accompanying drawings.

FIG. 1 is a schematic illustration of a quantum dot according to one or more embodiments of the present disclosure.

FIG. 2 is a flowchart illustrating a method of manufacturing the quantum dot of FIG. 1.

FIG. 3 is a flowchart illustrating the forming of a core of FIG. 2.

FIG. 4 is a schematic illustration explaining the temperature change if (e.g., when) the method of manufacturing the quantum dot of FIG. 2 is performed.

FIGS. 5, 6, 7, and 8 are each a graph of PL intensity versus wavelength for explaining for effects of the quantum dot of FIG. 1 and the method of manufacturing the quantum dot.

FIG. 9 is an image showing Comparative Examples 1-4.

FIG. 10 is an image showing Examples 1 and 2.

FIG. 11 is a plan view of a display device including the quantum dot of FIG. 1.

FIG. 12 is a cross-sectional view taken along the line I-I′ of FIG. 11.

### DETAILED DESCRIPTION

Hereinafter, display devices in accordance with embodiments will be described in more detail with reference to the accompanying drawings. The same reference numerals are used for the same components in the drawings, and redundant descriptions of the same components will not be provided.

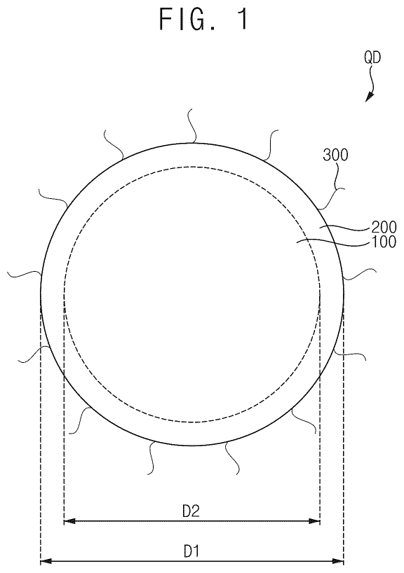

FIG. 1 is a schematic illustration of a quantum dot according to one or more embodiments of the present disclosure.

Referring to FIG. 1, a quantum dot QD according to one or more embodiments of the present disclosure may include a core 100, a shell 200, and a ligand 300. The core 100 may include AgInS₂, which is a semiconductor compound of a group I-III-VI (e.g., a group I-III-VI semiconductor compound). The shell 200 may be around (e.g., surround) the core 100. The ligand 300 may be bonded to the surface of the shell 200. In one or more embodiments, the quantum dot QD may be a quantum dot having a red emission wavelength (e.g., emitting red light).

The shell 200 may include gallium (Ga). For example, the shell 200 may be a GaSₓ shell including gallium (Ga) and sulfur(S). However, compositions of the shell 200 according to one or more embodiments of the present disclosure may not be limited thereto. The shell 200 of the quantum dot QD may serve as a protective layer to maintain semiconductor characteristics by preventing or reducing chemical modification of the core 100 and/or as a charging layer to impart electrophoretic characteristics to the quantum dot QD. The shell 200 may be a single layer or a multilayer. The interface between the core 100 and the shell 200 may have a concentration gradient in which the concentration of elements present in the shell 200 decreases toward a center.

The ligand 300 may improve the physical stability and chemical stability of the quantum dot QD so that adjacent quantum dots do not clump (e.g., aggregate) together during the manufacturing of the quantum dot QD. The ligand 300 may be an organic material. For example, the organic material may include trioctylphosphine (TOP), trioctylphosphine oxide (TOPO), oleic acid, oleylamine, octylamine, trioctylamine, hexadecylamine, octanethiol, dodecanethiol, hexylphosphonic acid (HPA), tetradecylphosphonic acid (TDPA), octylphosphonic acid (OPA), and/or the like. These materials may be used alone or in combination with each other.

In one or more embodiments, an average diameter D2 of the core 100 may be about 4.5 nm or more and about 12 nm or less. In one or more embodiments, the average diameter D2 of the core 100 may be about 6 nm or more and about 12 nm or less.

In one or more embodiments, the average diameter D1 of the core 100 and the shell 200 (together) may be about 6 nm or more and about 20 nm or less. In one or more embodiments, the average diameter D1 of the core 100 and the shell 200 may be about 8 nm or more and about 15 nm or less.

In one or more embodiments, an emission wavelength of the PL spectrum (photoluminescence spectroscopy) of the quantum dot QD may be about 600 nm or more. In one or more embodiments, the emission wavelength of the PL spectrum of the quantum dot QD may be about 600 nm or more and about 640 nm or less.

In one or more embodiments, a full width at a half maximum (FWHM) of an emission wavelength of the quantum dot QD may be about 50 nm or less. In one or more embodiments, the full width at the half maximum (FWHM) of the emission wavelength of the quantum dot QD may be about 40 nm or more and about 45 nm or less.

As described above, in the quantum dot QD according to one or more embodiments of the present disclosure, the average diameter D2 of the core 100 may be about 4.5 nm or more, and the FWHM (e.g., emission half-width) may be about 50 nm or less. For example, because the quantum dot QD has a core 100 of a bulk size (e.g., with a diameter of 4.5 nm or more) and has a narrow full width at half maximum of the emission wavelength, an emission efficiency of the quantum dot QD may be improved.

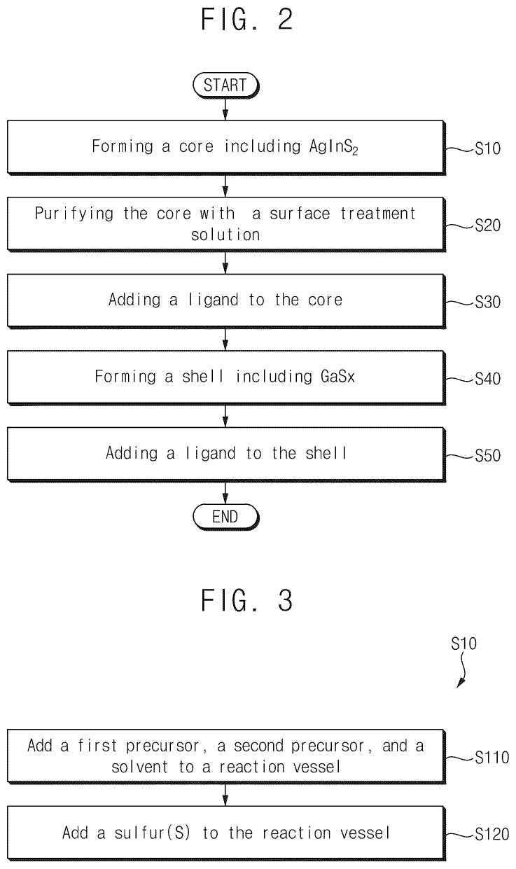

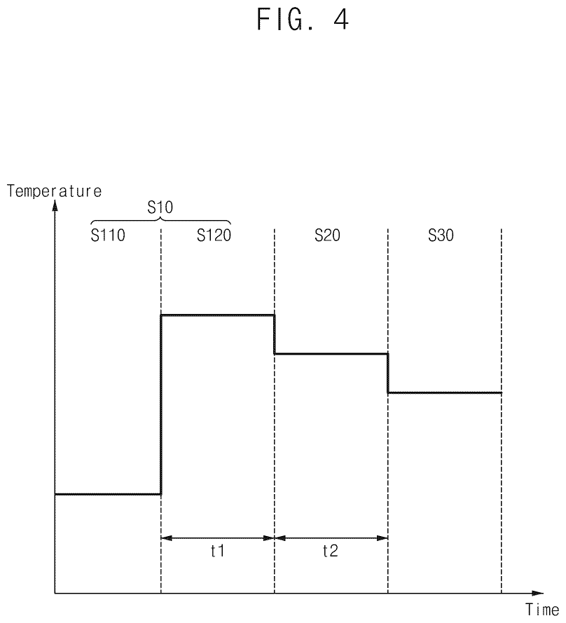

FIG. 2 is a flowchart illustrating a method of manufacturing the quantum dot of FIG. 1. FIG. 3 is a flowchart illustrating the forming of the core of FIG. 2. FIG. 4 is a schematic illustration for explaining a temperature change if (e.g., when) the method of manufacturing the quantum dot of FIG. 2 is performed.

Referring to FIGS. 2, 3, and 4, a method for manufacturing a quantum dot according to one or more embodiments of the present disclosure may include forming the core (e.g., the core 100 of FIG. 1) including AgInS₂ (S10), purifying the core with a surface treatment solution (S20), adding a ligand into the core (S30), forming a shell (e.g., the shell 200 of FIG. 1) including GaSₓ (S40), and adding a ligand to the shell (S50). The forming of the core (S10) may include adding a first precursor, a second precursor, and a solvent to a reaction vessel (S110) and adding sulfur(S) to the reaction vessel (S120). In the present disclosure, the first precursor and the second precursor may also be referred to as a second precursor including silver (Ag) and a third precursor including indium (In), respectively. For example, the first precursor may be referred to as the second precursor including (comprising) silver (Ag), and the second precursor may be referred to as the third precursor including (comprising) indium (In).

In the forming of the core (S10), an AgInS₂ core including silver (Ag) and indium (In) may be formed. In the adding of the first precursor, the second precursor, and the solvent to the reaction vessel (S110), the reaction vessel may provide a space for the core synthesis reaction. For example, the reaction vessel may be a synthesis flask. In one or more embodiments, a volume of the reaction vessel may be about 50 ml. However, the type (kind) and volume of the reaction vessel according to one or more embodiments of the present disclosure may not be limited thereto, and may have one or more suitable types (kinds) of containers or volumes.

The first precursor may include silver (Ag) (e.g., may be an Ag-containing precursor). In one or more embodiments, the first precursor may include AgF, AgCl, AgBr, AgI, Ag(NO₃), Ag(OAc), Ag(acac), Ag(DDTC), and/or the like. These materials may be used alone or in a combination with each other. The second precursor may include indium (In) (e.g., may be an In-containing precursor). In one or more embodiments, the second precursor may include InF₃, InCl₃, InBr₃, InI₃, In(NO₃)₃, In(OAc)₃, In(acac)₃, In(DDTC)₃, and/or the like. These materials may be used alone or in a combination with each other. The solvent may include ODE (octadecene), OLA (oleylamine), OA (oleic acid), and/or the like. These solvents may be used alone or in a combination with each other. Throughout the disclosure, in compounds containing OAc, acac and/or DDTC, OAc refers to an acetate group, acac refers to an acetylacetone group, and DDTC refers to a diethyldithiocarbamate group.

In one or more embodiments, the adding of the first precursor, the second precursor, and the solvent to the reaction vessel (S110) may be performed at a first temperature. For example, the first precursor, the second precursor, and the solvent may be added to the reaction vessel and reacted at the first temperature. In one or more embodiments, the first temperature may be about 100° C. to about 150° C. In one or more embodiments, the first temperature may be about 120° C.

In the adding of the sulfur(S) to the reaction vessel (S120), the sulfur(S) may be added to a solution formed by reacting the first precursor, the second precursor, and the solvent. For example, an S-OLA solution in which sulfur(S) is dissolved in OLA and a thiolate may be introduced into the reaction vessel. In one or more embodiments, the adding of sulfur(S) to the reaction vessel (S120) may be performed at a second temperature. The second temperature may be higher than the first temperature. For example, the second temperature may be about 220° C. or greater. In one or more embodiments, the second temperature may be about 240° C. or greater to about 280° C. or lower. For example, the second temperature may be about 260° C.

In one or more embodiments, the adding of the sulfur(S) to the reaction vessel (S120) may be performed for a first time (e.g., over a first duration) t1. For example, the first time t1 may be about 2 minutes or more and about 3 minutes or less. In one or more embodiments, the first time t1 may be about 2 minutes and 30 seconds.

After the adding of the sulfur(S) to the reaction vessel (S120) is performed for the first time t1, the purifying of the core with the surface treatment solution (S20) may be performed. In one or more embodiments, the purifying of the core (S20) may be performed at a third temperature. For example, the third temperature may be about 200° C.

In the purifying of the core with the surface treatment solution (S20), the surface treatment solution may be added to the reaction vessel after the third temperature is reached. In one or more embodiments, the surface treatment solution may include gallium (Ga). For example, the surface treatment solution may include GaI₃, Ga(acac)₃, and/or the like. These materials may be used alone or in a combination with each other.

In one or more embodiments, the purifying of the core with the surface treatment solution (S20) may be performed for a second time (e.g., over a second duration) t2. In one or more embodiments, the second time t2 may be greater than the first time t1. For example, the second time t2 may be about 8 minutes or more. In one or more embodiments, the second time t2 may be about 10 minutes. The adding of the ligand to the core (S30) may be performed between the purifying of the core with the surface treatment solution (S20) and the forming of the shell (S40). In one or more embodiments, the adding of the ligand to the core (S30) may be performed at a fourth temperature. In one or more embodiments, the fourth temperature may be lower than the third temperature. For example, the fourth temperature may be lower than about 200° C. In one or more embodiments, the fourth temperature may be about 180° C. In one or more embodiments, the ligand may include TOP. For example, in the adding of the ligand to the core (S30), a TOP solution may be injected into the reaction vessel. In one or more embodiments, the adding of the ligand into the core (S30) may be performed for about 20 minutes. For example, the TOP solution may be injected into the reaction vessel at about 180° C. and reacted for about 20 minutes.

After the adding of the ligand into the core (S30) is performed, the temperature may be lowered under the fourth temperature before the (e.g., act or task) step (S40) of forming the shell. For example, after the adding of the ligand into the core (S30) is performed, the temperature may be lowered to a room temperature before forming of the shell (S40), and a process related to the forming (e.g., generation) of the core may be terminated.

In forming of the shell (S40), the third precursor and the core may be reacted to form the shell. For example, in the forming of the shell (S40), a purified core, which is formed through the forming of the core in the reaction vessel (S10), the purifying of the core with the surface treatment solution (S20), the adding of the ligand to the core (S30), and the forming of the shell (S40), the third precursor, the sulfur(S), and the solvent may be added in the reaction vessel. In the present disclosure, the third precursor may be referred to as a third precursor including gallium (Ga).

In one or more embodiments, the third precursor may include GaF₃, GaCl₃, GaBr₃, GaI₃, Ga(NO₃)₃, Ga(OAc)₃, Ga(acac)₃, Ga(DDTC)₃, and/or the like. In the forming of the shell (S40), the third precursor may be added to the reaction vessel in a solution state dissolved in a solvent such as toluene. In the forming of the shell (S40), sulfur(S) may be added to the reaction vessel in a state of S-OLA. In the forming of the shell (S40), a nitrogen substitution reaction may proceed in the reaction vessel.

In the adding of the ligand to the shell (S50), the ligand may include a TOP. For example, in the adding of the ligand into the shell (S50), a solution of ZnCl₂ dissolved in the TOP and dodecyl mercaptan may be added. For example, in the adding of the ligand into the shell (S50), a reaction may proceed within the reaction vessel at about 200° C. for about 20 minutes after the solution of ZnCl₂ dissolved in the TOP and dodecyl mercaptan are added.

However, the temperatures at which each of the forming of the core (S10), the purifying of the core with the surface treatment solution (S20), the adding the ligand to the core (S30), the forming of the shell (S40), and the adding of the ligand into the shell (S50) according to one or more embodiments of the present disclosure is performed are provided as examples and the present disclosure is not limited thereto. The temperature at each act may have a variety of suitable temperatures (e.g., may be suitably adjusted).

As described above, in the method of manufacturing the quantum dot according to one or more embodiments of the present disclosure, a peak emission wavelength of the core may be confirmed before the shell is formed through the purifying of the core with the surface treatment solution (S20) performed after the forming of the core (S10). Accordingly, because it is easier to determine whether the quantum dot is well formed (e.g., meets the desired peak emission wavelength) during the process of manufacturing the quantum dot, cost and efficiency of the quantum dot manufacturing process may be improved. In addition, the quantum dot of a substantially uniform size may be easily manufactured.

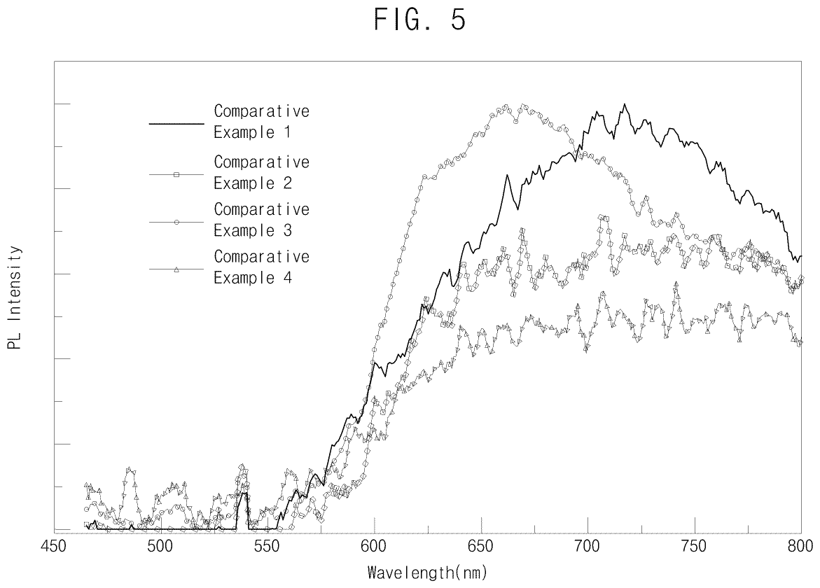

FIGS. 5, 6, 7, 8, 9, and 10 are graphs or images for explaining effects of the quantum dot of FIG. 1 and the method of manufacturing the quantum dot.

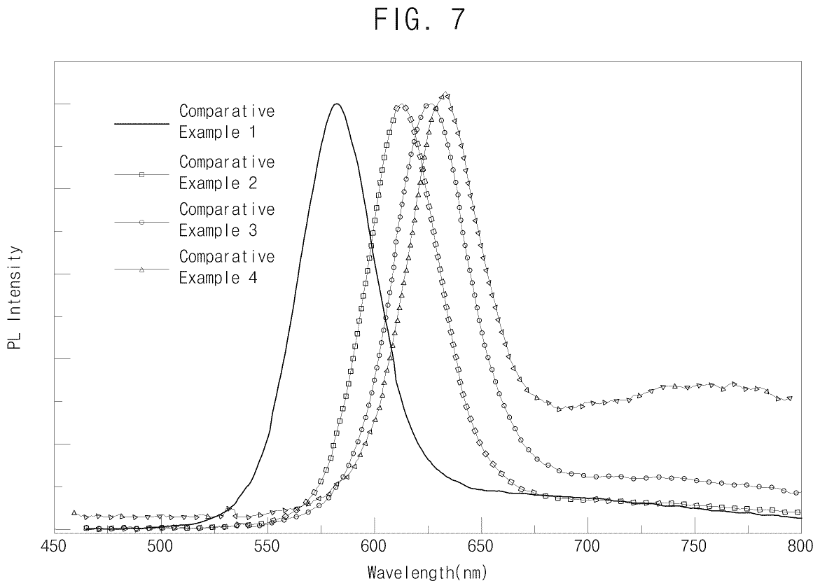

For example, FIG. 5 is a graph about a core of comparative examples, and FIG. 7 is a graph about a whole quantum dot including a core and a shell of the comparative examples.

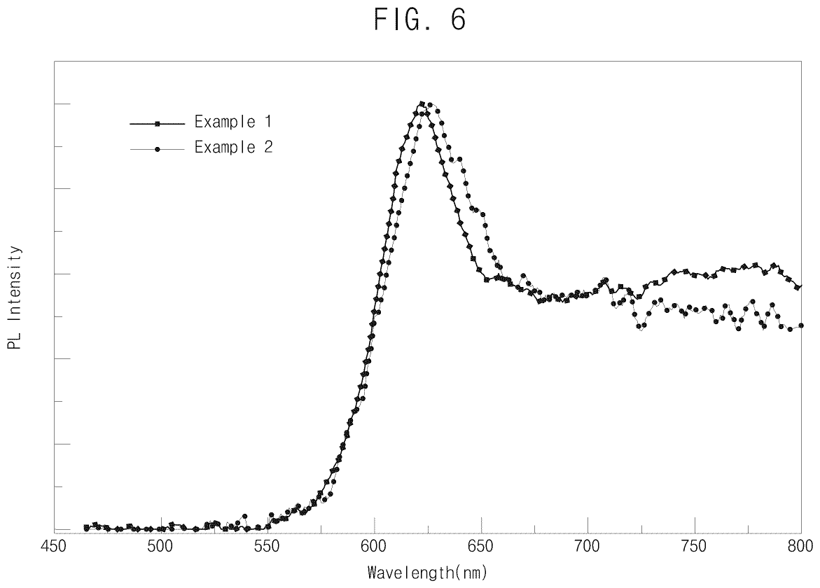

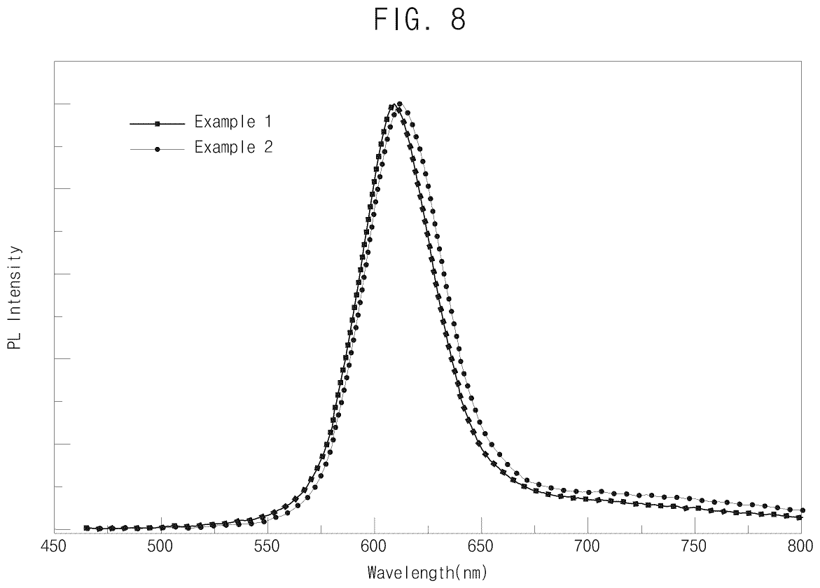

For example, FIG. 6 is a graph about a core of S examples, and FIG. 8 is a graph about a whole quantum dot including a core and a shell of the examples.

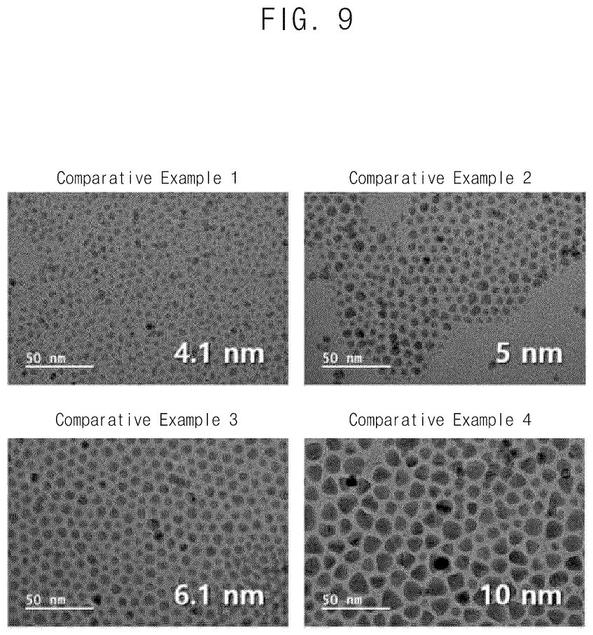

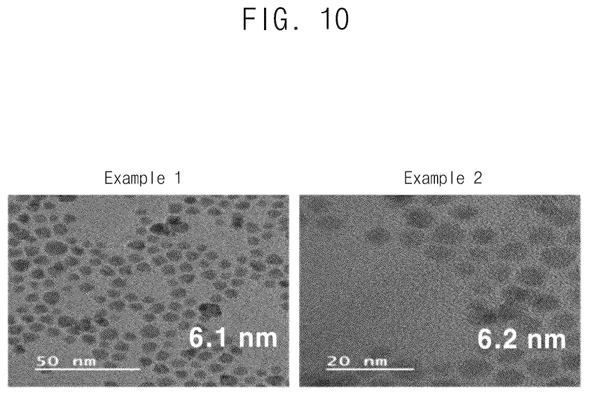

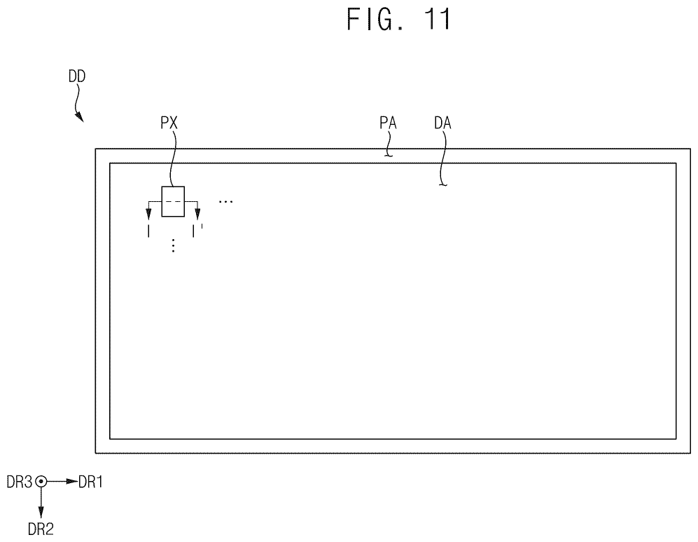

For example, FIGS. 9 and 10 are TEM images for explaining effects of the quantum dot of FIG. 1 and the method of manufacturing the quantum dot.

Hereinafter, effects of the present disclosure will be described with reference to examples and comparative examples.

### Manufactured Example 1: Formation of AgInS₂ Core

0.4 mmol of AgI, 0.9 mmol of InI₃, 2.5 ml of ODE, 2.5 ml of OA, and 5 ml of OLA were placed in a 50 ml synthesis flask, heated to 120° C., and a nitrogen substitution reaction was performed. Then, 1.6 ml of a S-OLA solution (1 M) and 1.6 ml of 1-octanethiol (Sigma-Aldrich, 98.5%) stock solution were placed in the synthesis flask, and the synthesis flask was heated to 200° C., and reacted for 2 minutes and 30 seconds. Thereafter, the temperature was lowered to 180° C., 4 ml of a TOP stock solution was placed in the synthesis flask, reacted for 20 minutes, and then the temperature was lowered to room temperature to form an AgInS₂ core.

### Manufactured Example 2: Formation of AgInS₂ Core and Treatment of Ga Solution

0.4 mmol of AgI, 0.9 mmol of InI₃, 2.5 ml of ODE, 2.5 ml of OA, and 5 ml of OLA were placed in a 50-mL synthesis flask, heated to 120° C., and nitrogen substitution reaction was performed. Then, 1.6 ml of an S-OLA solution (1 M) and 1.6 mL of a 1-octanethiol (Sigma-Aldrich, 98.5%) stock solution were placed in the synthesis flask, the synthesis flask was heated to 260° C., and reacted for 2 minutes and 30 seconds. Thereafter, the temperature was lowered to 200° C., and 1 ml of a Ga-OLA solution (1 M) including Ga(acac)₃ was placed in the synthesis flask, and reacted for 10 minutes. Afterwards, the temperature was lowered to 180° C., 4 mL of TOP solution was added to the synthesis flask, and reacted for 20 minutes, and then the temperature was lowered to room temperature to form an AgInS₂ core.

### Comparative Example 1

Comparative Example 1 is a AgInS₂/GaSₓ quantum dot manufactured by placing the AgInS₂ core manufactured according to Manufactured Example 1, 8 mL of OLA, a solution of 2.3 mmol GaCl₃ dissolved in 1 mL of toluene, and 1.6 mL of an S-OLA solution (1 M) in a 50 mL synthesis flask, heating to 200° C., and adding 0.5 mL of a ZnCl₂-TOP solution (0.63 M) and 0.5 mL of a 1-dodecanethiol (Sigma-Aldrich, 98.5%) stock solution to the synthesis flask and reacting for 20 minutes.

### Comparative Example 2

Comparative Example 2 is a AgInS₂/GaSₓ quantum dot manufactured through substantially the same manufacturing process as Comparative Example 1, except that during the manufacturing process of Manufactured Example 1, the 1.6 mL S-OLA solution (1 M) and the 1.6 mL of the stock solution of 1-octanethiol (Sigma-Aldrich, 98.5%) were placed in the synthesis flask and heated to 240° C. instead of 200° C.

### Comparative Example 3

Comparative Example 3 is a AgInS₂/GaSₓ quantum dot manufactured through substantially the same manufacturing process as Comparative Example 1, except that during the manufacturing process of Manufactured Example 1, the 1.6 mL S-OLA solution (1 M) and the 1.6 mL of the stock solution of 1-octanethiol (Sigma-Aldrich, 98.5%) were placed in the synthesis flask and heated to 260° C. instead of 200° C.

### Comparative Example 4

Comparative Example 4 is a AgInS₂/GaSₓ quantum dot manufactured through a manufacturing process substantially the same as Comparative Example 1, except that during the manufacturing process of Manufactured Example 1, the 1.6 mL S-OLA solution (1 M) and the 1.6 mL of the 1-octanethiol (Sigma-Aldrich, 98.5%) stock solution were placed in the synthesis flask and heated to 270° C. instead of 200° C.

Referring to FIGS. 5, 6, 7, 8, 9, and 10, Example 1 is a AgInS₂/GaSₓ quantum dot manufactured by placing the AgInS₂ core manufactured according to Manufactured Example 2, 8 mL of OLA, a solution of 2.3 mmol GaCl₃ dissolved in 1 mL toluene, and 1.6 mL of S-OLA (1 M) in a 50 mL synthesis flask, heating to 200° C., and adding 0.5 mL ZnCl₂-TOP (0.63 M) and 0.5 mL 1-dodecanethiol (Sigma-Aldrich, 98.5%) stock solution to the synthesis flask and reacting for 20 minutes. Example 2 is a quantum dot manufactured through substantially the same manufacturing process as Example 1, except that 1 mL Ga-OLA (0.5 M) including Gals instead of Ga(acac)₃ was added to the synthesis flask during the manufacturing process of Manufactured Example 2.

A peak emission wavelength of the core according to the PL spectrum measured during the core formation process of each of the comparative examples and examples illustrated in FIGS. 5 and 6 is shown in Table 1.

TABLE 1

| Example Type | Peak emission wavelength(nm) |
|---|---|
| Comparative Example 1 | — |
| Comparative Example 2 | — |
| Comparative Example 3 | — |
| Comparative Example 4 | — |
| Example 1 | 623 |
| Example 2 | 627 |

Referring to Table 1 above, the peak mission wavelength was 600 nm or more in Examples 1 and 2 in which the core was surface-treated with a gallium solution of Ga-OLA at 200° C. In addition, the peak emission wavelength of the core may not be specified (e.g., are difficult to determine accurately) in Comparative Examples 1, 2, 3, and 4 in which the core was not surface-treated. Accordingly, in a case a process of purifying the core with the gallium solution (e.g. the purifying of the core with the surface treatment solution (S20) of FIG. 2) among the process of forming of the core (e.g., the forming of the core (S10) of FIG. 2, the purifying of the core with the surface treatment solution (S20), and the adding of the ligand to the core (S30)), was performed, the peak emission wavelength was confirmed even in a core forming process before forming the shell. Accordingly, because whether the core is well formed before forming the shell may be easy to be determined, cost and efficiency of the quantum dot manufacturing process may be improved. In addition, quantum dot of a substantially uniform size may be easily manufactured.

A peak emission wavelength, a full width at a half maximum of an emission wavelength, and a fluorescence yield of each of the comparative examples and examples illustrated in FIGS. 7 and 8 are as shown in Table 2.

TABLE 2

| | Peak | Full width at | |
|---|---|---|---|
| | emission | half maximum | |
| | wavelength | of an emission | Fluorescence |
| Example Type | (nm) | wavelength (nm) | yield (%) |
| Comparative Example 1 | 582 | 43.7 | 71.2 |
| Comparative Example 2 | 613 | 41.2 | 63.1 |
| Comparative Example 3 | 627 | 43.6 | 48 |
| Comparative Example 4 | 639 | 44.7 | 24 |
| Example 1 | 609 | 41.8 | 47.9 |
| Example 2 | 612 | 44.2 | 58.5 |

Referring to Table 2 above, the full width at half maximum of the emission wavelength of the quantum dot having the core/shell structure of each of Comparative Examples 1, 2, 3, and 4, Example 1, and Example 2 was 50 nm or less. In addition, the peak emission wavelength, the full width at half maximum of the emission wavelength, and the fluorescence yield of Comparative Example 3, Example 1, and Example 2, in which the S-OLA solution and the 1-octanethiol solution were added during the process of forming the core and reacted at 260° C., were similar. Accordingly, characteristics of the quantum dot manufactured by performing the process of surface-treating of the core with the gallium solution in the process of forming the core were not significantly different from those of the quantum dot manufactured without performing the process of surface-treating the core with a gallium solution.

The table 1 is about core, and the table 2 is about a whole quantum dot which includes a core and a shell.

An average diameter of the core of each of the comparative examples and embodiments illustrated in FIGS. 9 and 10 is shown in Table 3.

TABLE 3

| Example Type | Average diameter of the core (nm) |
|---|---|
| Comparative Example 1 | 4.1 |
| Comparative Example 2 | 5 |
| Comparative Example 3 | 6.1 |
| Comparative Example 4 | 10 |
| Example 1 | 6.1 |
| Example 2 | 6.2 |

Referring to Table 3 above, the greater the temperature at which the S-OLA solution and the 1-octanethiol solution were added and reacted (e.g., the second temperature at which the adding of the sulfur(S) to the reaction vessel (S120) of FIG. 2 was performed), the greater the average diameter of the core. In the Comparative Examples 3 and 4, and Example 1 and Example 2, because the S-OLA solution and the 1-octanethiol solution were added and reacted at 240° C. or higher, the second temperature, which is desired or required to form cores having a bulk size of a diameter of 4.5 nm or more, was confirmed.

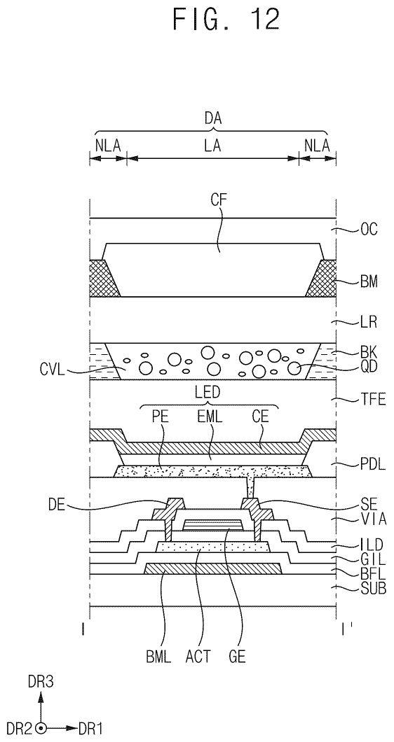

FIG. 11 is a plan view of a display device including the quantum dot of FIG. 1. FIG. 12 is a cross-sectional view taken along the line I-I′ of FIG. 11.

The display device DD described with reference to FIGS. 11 and 12 may include the quantum dot QD of FIG. 1. For example, a color conversion pattern CVL may include the quantum dot QD. Hereinafter, any content (e.g., description) that overlaps with the content (e.g., description) of the quantum dot QD described with reference to FIG. 1 may not be provided or simplified.

Referring to FIGS. 1, 11, and 12, the display device DD according to one or more embodiments of the present disclosure may include a display area DA and a peripheral area PA. The display area DA may include a light-emitting area LA and a non-light-emitting area NLA adjacent to the light-emitting area LA.

The display area DA may be an area that generates light or may display an image by controlling a transmittance of light provided from an external light source. At least one pixel PX that emits light may be arranged in the display area DA.

In this disclosure, a plane may be defined by a first direction DR1 and a second direction DR2 intersecting the first direction DR1. For example, the first direction DR1 and the second direction DR2 may be normal (e.g., perpendicular) to each other. In addition, a third direction DR3 may be normal (e.g., perpendicular) to the plane.

A plurality of pixels PX may be arranged within the display area DA. For example, the pixels PX may be arranged in the first direction DR1 and the second direction DR2 within the display area DA in the form of a matrix. The plurality of pixels PX may be to emit light of different colors. For example, the plurality of pixels PX may include a first pixel for emitting a first light, a second pixel for emitting a second light, and a third pixel for emitting a third light. For example, the first light may have a green color, the second light may have a red color, and the third light may have a blue color. However, the color of light emitted by the pixel PX according to one or more embodiments of the present disclosure is not limited thereto, and may be to emit light having one or more suitable colors such as magenta, cyan, and/or yellow.

The peripheral area PA may be around (e.g., surround) at least a portion of the display area DA. For example, the peripheral area PA may be entirely around (e.g., surround) the display area DA in a plan view. The peripheral area PA may be defined as an area that does not emit light and does not generate an image. A driver for driving the pixel PX may be arranged in the peripheral area PA. The driver may provide a signal and/or voltage to the pixel PX.

The display device DD may include a substrate SUB, a bottom metal layer BML, a buffer layer BFL, an active layer ACT, a gate insulating layer GIL, a gate electrode GE, an interlayer insulating layer ILD, a source electrode SE, a drain electrode DE, a via insulating layer VIA, a pixel electrode PE, a pixel defining layer PDL, a light-emitting layer EML, a common electrode CE, an encapsulation layer TFE, a color conversion pattern CVL, a bank layer BK, a refractive layer LR, a color filter CF, a light-blocking pattern BM, and a planarization layer OC. The pixel electrode PE, the light-emitting layer EML, and the common electrode CE may together define a light-emitting element LED. The active layer ACT, the gate electrode GE, the source electrode SE, and the drain electrode DE may together define a transistor.

The substrate SUB may serve as a base for the pixel PX. The substrate SUB may include a transparent or opaque material. In one or more embodiments, examples of materials which are used as the substrate SUB include glass, quartz, plastic, and/or the like. These materials may be used alone or in a combination with each other.

The bottom metal layer BML may be arranged on the substrate SUB. The bottom metal layer BML may prevent or substantially prevent impurities from being introduced into the substrate SUB or prevent or substantially prevent static electricity from occurring in the active layer ACT. The bottom metal layer BML may include a conductive material.

The buffer layer BFL may be arranged on the bottom metal layer BML. The buffer layer BFL may prevent or substantially prevent metal atoms or impurities from diffusing from the substrate SUB to the active layer ACT. In addition, the buffer layer BFL may control the rate at which heat is provided during the crystallization process for forming the active layer. The buffer layer BFL may include an insulating material.

The active layer ACT may be arranged on the buffer layer BFL. The active layer ACT may include a source area connected to the source electrode SE, a drain area connected to the drain electrode DE, and a channel area arranged between the source area and the drain area. The active layer ACT may include polycrystalline silicon, an oxide semiconductor, and/or the like.

The gate insulating layer GIL may be arranged on the active layer ACT. The gate insulating layer GIL may include an inorganic insulating material. In one or more embodiments, the gate insulating layer GIL may cover the upper surface of the active layer ACT along a profile of the active layer ACT. However, the gate insulating layer GIL according to one or more embodiments of the present disclosure may not be limited thereto, and the gate insulating layer GIL may not generate a step (e.g., unevenness) around the active layer ACT and may have a substantially flat upper surface.

The gate electrode GE may be arranged on the gate insulating layer GIL. The gate electrode GE may overlap the active layer ACT in a plan view. For example, the channel area may be defined as a portion of an active layer ACT overlapping a gate electrode GE. The gate electrode GE may include a conductive material.

An interlayer insulating layer ILD may be arranged on the gate electrode GE. The interlayer insulating layer ILD may include an inorganic insulating material. In one or more embodiments, the interlayer insulating layer ILD may cover an upper surface of the gate electrode GE along a profile of the gate electrode GE. However, the interlayer insulating layer ILD according to one or more embodiments of the present disclosure may not be limited thereto, and the interlayer insulating layer ILD may have a substantially flat upper surface without generating a step around the gate electrode GE.

A source electrode SE and a drain electrode DE may be arranged on the interlayer insulating layer ILD. The source electrode SEand the drain electrode DE may contact the source area and the drain area, respectively, through openings penetrating the interlayer insulating layer ILD and the gate insulating layer GIL in the third direction DR3. Each of the source electrode SE and the drain electrode DE may include a conductive material.

A via insulating layer VIA may be arranged on the source electrode SE and the drain electrode DE. The via insulating layer VIA may include an organic insulating material. The via insulating layer VIA may have a substantially flat upper surface.

A pixel electrode PE may be arranged on the via insulating layer VIA. In one or more embodiments, the pixel electrode PE may contact the source electrode SE through an opening penetrating the via insulating layer VIA in the third direction DR3. However, according to one or more embodiments of the present disclosure, the pixel electrode PE may not be limited thereto, and the pixel electrode PE may contact the drain electrode DE through the opening. The pixel electrode PE may include a conductive material.

The pixel defining layer PDL may be arranged on the via insulating layer VIA. The pixel defining layer PDL may partially cover the pixel electrode PE. For example, an opening that exposes the center of the pixel electrode PE is defined in the pixel defining layer PDL, and the pixel defining layer PDL may cover the edge of the pixel electrode PE.

The light-emitting layer EML may be arranged on the pixel electrode PE. The light-emitting layer EML may be arranged on the pixel electrode PE exposed by the opening of the pixel defining layer PDL. The light-emitting layer EML may include an organic light-emitting material, a quantum dot, and/or the like. The light-emitting layer EML may be arranged in the light-emitting area LA.

A common electrode CE may be arranged on the emission layer EML and the pixel defining layer PDL. The common electrode CE may include a conductive material. The common electrode CE may be arranged across the light-emitting area LA and the non-light-emitting area NLA.

The encapsulation layer TFE may be arranged on the common electrode CE. The encapsulation layer TFE may cover the light-emitting element LED. In one or more embodiments, the encapsulation layer TFE may include at least one organic layer and at least one inorganic layer. However, the encapsulation layer TFE according to one or more embodiments of the present disclosure may not be limited thereto, and the encapsulation layer TFE may be a substrate including glass, and/or the like.

The color conversion pattern CVL may be arranged on the encapsulation layer TFE. The color conversion pattern CVL may overlap with the emission layer EML. The color conversion pattern CVL may be arranged in the light-emitting area LA. The color conversion pattern CVL may include a quantum dot QD of FIG. 1 having a red emission wavelength (e.g., emitting red light). The color conversion pattern CVL may convert the wavelength of light emitted from the emission layer EML. For example, if (e.g., when) light emitted from the emission layer EML overlapping the color conversion pattern CVL including the quantum dot QD having a red emission wavelength passes through the color conversion pattern CVL, red light may be emitted. However, the color of light passing through the color conversion pattern CVL according to one or more embodiments of the present disclosure may not be limited thereto, and another color conversion pattern CVL adjacent to the color conversion pattern CVL including a quantum dot QD having a red emission wavelength may pass light of a color other than red.

In one or more embodiments, the color conversion pattern CVL may include a fluorescent substance, a scattering substance, a quantum dot, and/or the like. The color conversion pattern CVL may include a resin portion around (e.g., surrounding) the quantum dot QD. The resin portion may include a polymer resin, and/or the like.

The bank layer BK may be arranged on the encapsulation layer TFE. The bank layer BK may be formed of a light-blocking material and may block light emitted from below. In addition, an opening exposing the sealing layer TFE may be formed in the bank layer BK.

The refractive layer LR may be arranged on the color conversion pattern CVL. The refractive layer LR may have a set or predetermined refractive index different from adjacent layers (e.g., different from the color conversion pattern CVL). Accordingly, the light efficiency of the display device may be improved. However, the refractive layer LR according to one or more embodiments of the present disclosure may not be limited thereto, and the refractive layer LR may be arranged below the color conversion pattern CVL. In addition, the refractive layer LR may have a single-layer structure or a multi-layer structure.

The color filter CF may be arranged on the refractive layer LR. The color filter CF may overlap with the light-emitting layer EML and the color conversion pattern CVL. The color filter CF may be to transmit light of a wavelength corresponding to light emitted from the light-emitting layer EML overlapping the color filter CF. For example, the color filter CF overlapping the color conversion pattern CVL including the quantum dot QD having a red emission wavelength may be to transmit red light. However, the color filter CF according to one or more embodiments of the present disclosure may not be limited thereto, and the color filter CF that does not overlap the quantum dot QD having a red emission wavelength may be to transmit light of a color other than red.

The light-blocking pattern BM may be arranged on the refractive layer LR. The light-blocking pattern BM may be formed of a light-blocking material and may block light emitted from below. In addition, an opening may be formed in the light-blocking pattern BM that exposes the refractive layer LR. The light-blocking pattern BM may be arranged in the non-emitting area NLA.

The planarization layer OC may be arranged on the color filter CF. The planarization layer OC may be formed of an organic material and may provide a substantially flat upper surface.

While the quantum dot QD according to one or more embodiments of the present disclosure are illustrated as being included in the color conversion pattern CVL, one or more embodiments may not be limited to thereto, and the quantum dot QD may be included in the light-emitting layer EML.

As described above, a quantum dot QD with the average diameter of the core 100 according to one or more embodiments of the present disclosure of about 4.5 nm or more (e.g., more than 4.5 nm) and about 12 nm or less and have a full width at a half maximum of an emission wavelength which is about 50 nm or less. Accordingly, because the quantum dot QD has the core 100 of a bulk size and has the narrow full width at the half maximum of the emission wavelength, a display quality of the display device DD may be improved.

The method, the quantum dot and the device according to one or more embodiments may be applied to an electronic device, for example, a display device included in a computer, a notebook, a mobile phone, a smartphone, a smart pad, a PMP, a PDA, an MP3 player, a TV, a monitor, a tablet, an electric vehicles, and/or the like.

Unless otherwise especially defined in this description, a particle diameter may be an average particle diameter. In addition, a particle diameter indicates an average particle diameter (D₅₀) where a cumulative volume is about 50 volume % in a particle size distribution. The average particle diameter (D₅₀) may be measured by a suitable method, for example, by a particle size analyzer, a transmission electron microscope (TEM) image, or a scanning electron microscope (SEM) image. In one or more embodiments, a dynamic light-scattering measurement device is used to perform a data analysis, the number of particles is counted for each particle size range, and then from this, an average particle diameter (D₅₀) value may be obtained through a calculation. Dissimilarly, a laser scattering method may be utilized to measure the average particle diameter (D₅₀). In the laser scattering method, target particles are distributed in a dispersion solvent, introduced into a laser scattering particle size measurement device (e.g., MT3000 commercially available from Microtrac, Inc), irradiated with ultrasonic waves of 28 kHz at a power of 60 W, and then an average particle diameter (D₅₀) is calculated in the 50% standard of particle diameter distribution in the measurement device.

As used herein, the terms “use,” “using,” and “used” may be considered synonymous with the terms “utilize,” “utilizing,” and “utilized,” respectively. As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The use of “may” when describing embodiments of the inventive concept refers to “one or more embodiments of the inventive concept.”

As used herein, the term “about,” and similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Here, unless otherwise defined, the listing of steps, tasks, or acts in a particular order should not necessarily means that the invention or claims require that particular order. That is, the general rule that unless the steps, tasks, or acts of a method (e.g., a method claim) actually recite an order, the steps, tasks, or acts should not be construed to require one.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The display device, the electronic device, a device for manufacturing the same (e.g., the quantum dot) and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Although the method, the quantum dot and the device according to one or more embodiments have been described with reference to the drawings, the illustrated embodiments are examples, and may be modified and changed by a person having ordinary knowledge in the relevant technical field without departing from the technical spirit described in the following claims and equivalents thereof.

What is claimed is:

1. A method comprising:
forming a core comprising silver (Ag) and indium (In);
purifying the core with a surface treatment solution comprising gallium (Ga); and
forming a shell around the core by reacting a first precursor comprising gallium (Ga) with the core,
wherein the method is a method of manufacturing a quantum dot.

2. The method of claim 1, wherein the surface treatment solution comprises at least one selected from the group consisting of Gals and Ga(acac)₃.

3. The method of claim 1, wherein the purifying of the core is performed between the forming of the core and the forming of the shell.

4. The method of claim 1, wherein after the purifying of the core, a peak emission wavelength of a photoluminescence (PL) spectrum of the core is about 600 nm or more.

5. The method of claim 1, wherein the forming of the core comprises:
adding a second precursor comprising Ag and a third precursor comprising In to a reaction vessel; and
adding sulfur(S) to the reaction vessel.

6. The method of claim 5, wherein the second precursor comprises at least one selected from the group consisting of AgF, AgCl, AgBr, AgI, Ag(NO₃), Ag(OAc), Ag(acac), and Ag(DDTC).

7. The method of claim 5, wherein the third precursor comprises at least one selected from the group consisting of InF₃, InCl₃, InBr₃, InI₃, In(NO₃)₃, In(OAc)₃, In(acac)₃, and In(DDTC)₃.

8. The method of claim 5, wherein
the adding of the third precursor is performed at a first temperature, and
the adding of sulfur is performed at a second temperature over a first duration.

9. The method of claim 8, wherein
the second temperature is greater than the first temperature, and
the second temperature is greater than about 220° C.

10. The method of claim 8, wherein in the purifying of the core, the core and the surface treatment solution react at a third temperature lower than the second temperature.

11. The method of claim 10, wherein in the purifying of the core, the core and the surface treatment solution react over a second duration longer than the first duration.

12. The method of claim 11, wherein between the purifying of the core and the forming of the shell, the method further comprises adding a ligand to the core at a fourth temperature lower than the third temperature.

13. The method of claim 1, wherein in the forming of the shell, sulfur is added to react with the core and the first precursor.

14. The method of claim 1, wherein the first precursor comprises at least one selected from the group consisting of GaF₃, GaCl₃, GaBr₃, GaI₃, Ga(NO₃)₃, Ga(OAc)₃, Ga(acac)₃ and Ga(DDTC)₃.

15. The method of claim 1, wherein the core comprises AgInS₂.

16. The method of claim 1, wherein the shell comprises Ga.

17. A quantum dot comprising:
a core comprising silver (Ag) and indium (In); and
a shell around the core, and comprising gallium (Ga) and sulfur(S),
wherein a full width at half maximum of an emission wavelength of the quantum dot is about 50 nm or less, and a peak emission wavelength of a photoluminescence (PL) spectrum of the quantum dot is about 600 nm or more.

18. The quantum dot of claim 17, wherein an average diameter of the core is about 4.5 nm or more and about 12 nm or less.

19. An electronic device comprising a quantum dot, the quantum dot comprising:
a core comprising silver (Ag) and indium (In); and
a shell around the core, and comprising gallium (Ga) and sulfur(S),
wherein a full width at half maximum of an emission wavelength of the quantum dot is about 50 nm or less, and a peak emission wavelength of a photoluminescence (PL) spectrum of the quantum dot is about 600 nm or more.

20. The electronic device of claim 19, wherein an average diameter of the core is about 4.5 nm or more and about 12 nm or less.
